(19) United States
(12) Patent Application Publication
(10) Pub. No.: US 2022/0094138 A1
(43) Pub. Date: Mar. 24, 2022

(54) STACKED-TYPE OPTICAL COMMUNICATION MODULE AND MANUFACTURING METHOD THEREOF

(71) Applicant: ELECTRONICS AND TELECOMMUNICATIONS RESEARCH INSTITUTE, Daejeon (KR)

(72) Inventors: Eun Kyu KANG, Gwangju (KR); Jong Jin LEE, Gwangju (KR); Dae Seon KIM, Gwangju (KR); Eun Kyoung JEON, Gwangju, Gyeongsangnam-do (KR); Sang Jin KWON, Gwangju (KR); Won Bae KWON, Jeollanam-do (KR); Kwon Seob LIM, Jeollanam-do (KR); Soo Yong JUNG, Gwangju (KR)

(73) Assignee: ELECTRONICS AND TELECOMMUNICATIONS RESEARCH INSTITUTE, Daejeon (KR)

(21) Appl. No.: 17/479,496

(22) Filed: Sep. 20, 2021

(30) Foreign Application Priority Data
Sep. 21, 2020 (KR) 10-2020-0121652
Dec. 16, 2020 (KR) 10-2020-0176413

(51) Int. Cl. H01S 5/024; G02B 27/28; H01S 5/02257; H01S 5/02253; H01S 5/02255; H04J 14/02; H04B 10/40

(52) U.S. Cl. CPC H01S 5/02469; G02B 27/283; H01S 5/02257; H04B 10/25; H01S 5/02255; H04J 14/02; H04B 10/40; H01S 5/02253

(57) ABSTRACT

A structure and a manufacturing method of an optical transmission module, in which output light of each of a first optical transmission unit and a second optical transmission unit is combined into one and transmitted through an optical fiber. In order to manufacture the optical transmission module, the first optical transmission unit and the second optical transmission unit are separately manufactured using a wafer-level packaging process and then are stacked. As a result, emission of generated heat is divided into a first heat sink installed in the first optical transmission unit and a second heat sink installed in the second optical transmission unit so that better heat dissipation efficiency is achieved than a conventional optical transmission module. In addition, a mounting area may also be reduced to ½ of the conventional module.

### CROSS-REFERENCE TO RELATED APPLICATIONS

This application claims priority to and the benefit of Korean Patent Applications No. 10-2020-0121652, filed on Sep. 21, 2020, and No. 10-2020-0176413, filed on Dec. 16, 2020, the disclosures of which are incorporated herein by reference in its entirety.

### BACKGROUND

### 1. Field of the Invention

The present disclosure relates to a multi-channel optical communication module used in an optical network.

### 2. Discussion of Related Art

Recently, as data traffic rapidly increases, an optical transmission/reception module capable of transmitting a large amount of data at a high speed without distortion of signals has been in the spotlight. To this end, the miniaturization of an optical transceiver module package is an important issue.

In the case of a multi-channel transmitter optical subassembly (TOSA) module used in a conventional optical network, transmission channels are horizontally arranged. Thus, heat of the module may only be dissipated in one direction, downward or upward, and an area of the module in a horizontal direction increases as the channels extend, which may become a limiting factor when the module is used in an optical transceiver or printed circuit board (PCB) mounted type on-board optics.

### SUMMARY OF THE INVENTION

The present disclosure is directed to providing an optical transmission module capable of emitting heat more efficiently and easily than a conventional optical transmission module and simultaneously reducing a mounting area by providing a structure that may efficiently discharge heat in order to solve a problem of dissipation of heat generated in a multi-channel optical transmission module, and a manufacturing method thereof.

In order to achieve the above-described objective, provided are a structure and a manufacturing method of an optical transmission module, in which output light of each of a first optical transmission unit and a second optical transmission unit is combined into one and transmitted through an optical fiber, and completed by separately manufacturing the first optical transmission unit and the second optical transmission unit, each having optical elements and related elements that are assembled, and stacking the first optical transmission unit and the second optical transmission unit.

In order to manufacture the optical transmission module, the first optical transmission unit and the second optical transmission unit are separately manufactured using a wafer-level packaging process and then are stacked. As a result, emission of generated heat is divided into a first heat sink installed in the first optical transmission unit and a second heat sink installed in the second optical transmission unit so that better heat dissipation efficiency is achieved than a conventional optical transmission module. In addition, a mounting area may also be reduced to ½ of the conventional module.

According to an aspect of the present disclosure, there is provided a stacked-type optical communication module including a first optical transmission unit manufactured using a wafer-level packaging process, a first heat sink comprised in the first optical transmission unit and configured to emit heat generated by the first optical transmission unit, a second optical transmission unit manufactured using the wafer-level packaging process and stacked on the first optical transmission unit, and a second heat sink comprised in the second optical transmission unit and configured to emit heat generated by the second optical transmission unit.

According to another aspect of the present disclosure, there is provided a method of manufacturing a stacked-type optical communication module including manufacturing a first optical transmission unit using a wafer-level packaging process, attaching a first heat sink, which is configured to emit heat, to the first optical transmission unit, manufacturing a second optical transmission unit using the wafer-level packaging process, attaching a second heat sink, which is configured to emit heat, to the second optical transmission unit, and stacking the first optical transmission unit and the second optical transmission unit.

The above-described configurations and operations of the present disclosure will become more apparent from embodiments described in detail below with reference to the drawings.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 illustrates an internal configuration diagram of a bottom optical transmission unit according to one embodiment of the present disclosure and a light path;

FIG. 2 is an external view of the bottom optical transmission unit covered with a cover glass;

FIG. 3 illustrates an internal block diagram of a top optical transmission unit and a light path;

FIG. 4 illustrates a configuration diagram of an optical transmission module, in which the bottom and top optical transmission units are coupled, and a light path;

FIGS. 5A to 5C are schematic diagrams of a packaging sequence of a 2-Ch optical transmission module; and

FIG. 6 is an internal configuration diagram of a 4-Ch bottom optical transmission unit.

### DETAILED DESCRIPTION OF EXEMPLARY EMBODIMENTS

Advantages and features of the present disclosure and methods for achieving them will be made clear from embodiments described in detail below with reference to the accompanying drawings. However, the present disclosure may be implemented in many different forms and should not be construed as being limited to the embodiments set forth herein. Rather, these embodiments are provided so that this disclosure will be thorough and complete and will fully convey the scope of the present disclosure to those of ordinary skill in the technical field to which the present disclosure pertains. The present disclosure is defined by the claims. Meanwhile, terms used herein are for the purpose of describing the embodiments and are not intended to limit the present disclosure. As used herein, the singular forms comprise the plural forms as well unless the context clearly indicates otherwise. The term “comprise” or “comprising” used herein does not preclude the presence or addition of one or more other elements, steps, operations, and/or devices other than stated elements, steps, operations, and/or devices. Hereinafter, exemplary embodiments of the present disclosure will be described in detail with reference to the accompanying drawings. Further, in describing the present disclosure, the detailed description of a related known configuration or function will be omitted when it obscures the gist of the present disclosure.

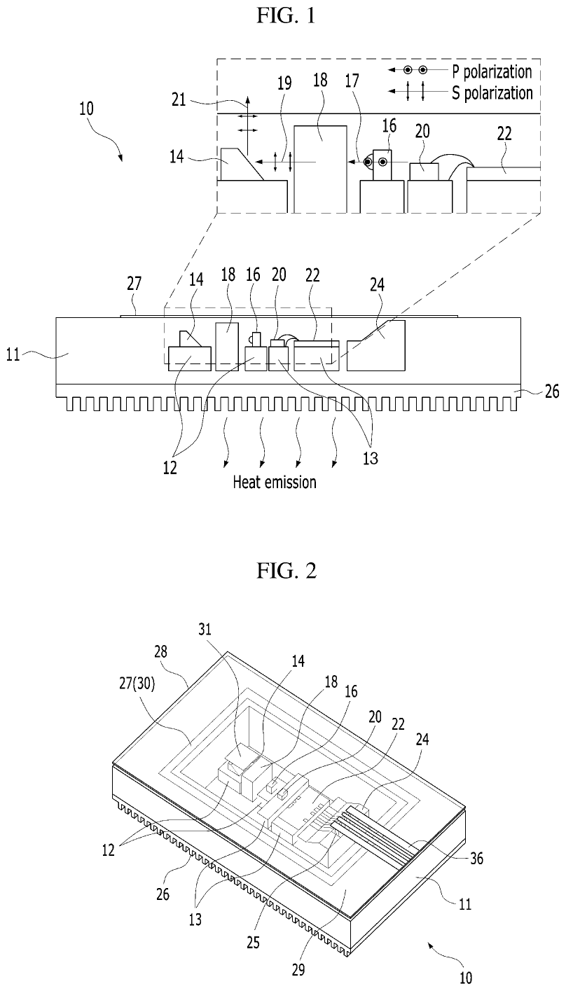

FIG. 1 is an interior cross-sectional view of a bottom optical transmission unit 10, which is a first part of a stacked-type optical transmission module, according to an exemplary embodiment of the present disclosure. A submount 12 for a lens is formed on a silicon optical bench (SiOB) 11 used as a substrate, and a mirror 14 and a collimating or focusing lens 16 are installed on the submount 12. A half-wave plate 18 is installed between the mirror 14 and the lens 16. In addition, a dielectric submount 13 is formed adjacent to the lens 16, and on the dielectric submount 13, a laser diode (LD) 20 and an LD driver (LDD) 22 are formed. A dielectric submount 24 for a transmission line, which has a surface on which a transmission line 25 (FIG. 2) is formed, is installed adjacent to the LDD 22, and the transmission line 25 is connected to the LDD 22. In addition, a heat sink 26 is attached to an outside of a bottom surface of the SiOB 11 to emit heat. A solder layer 27 for a subsequent sealing operation with a cover glass is formed on a surface of the SiOB 11 at a periphery of the above-described inner components.

A light path of the bottom optical transmission unit 10 is illustrated in an enlarged view shown in an upper portion of FIG. 1. A P-polarization beam 17 emitted from the LD 20 is converted into a collimated or focused beam depending on whether the type of the lens 16 is a collimating or focusing lens, and is input to the half-wave plate 18. Polarization of the input beam is rotated by 90° by the half-wave plate 18, and thus the input beam is converted into an S-polarization beam 19. The converted beam is reflected by the mirror 14 and has a direction changed by 90°, and is emitted as an output light 21 to the outside.

FIG. 2 is a top perspective view of the bottom optical transmission unit 10 covered with a cover glass. 1-Ch transmitter which has one transmission channel is illustrated.

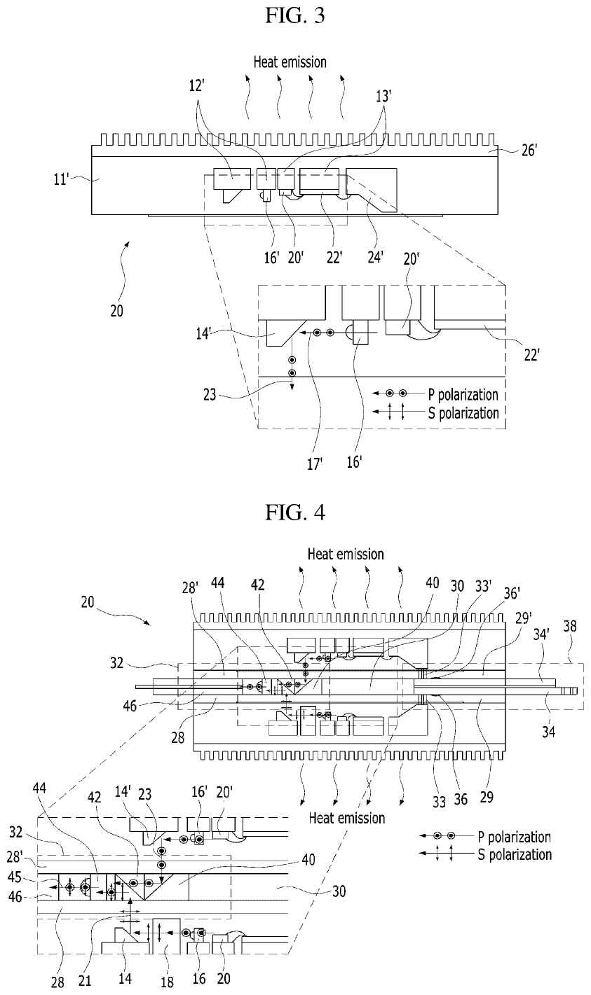

After the internal components shown in FIG. 1 are assembled, a cover glass 28 including an interposer region 29 is covered thereon, and the solder layer 27 on the surface of the SiOB 11 and a solder layer 30 on an inner side of the cover glass 28 are bonded and sealed to complete the bottom optical transmission unit 10. Since the bottom optical transmission unit (and a top optical transmission unit) is sealed by the optically transparent cover glass 28, light from an internal light source may be output to the outside with little loss. The above-described configuration of covering with the cover glass may be equally applied to the case of the top optical transmission unit (FIG. 3).

Further, an anti-reflective (AR) coating portion 31 is comprised in the cover glass 28 (preferably on an inner side) so that the output light 21 emitted to the outside from the mirror 14 located below the cover glass 28 is not reflected by the cover glass 28 and is completely emitted to the outside. In addition, one side of the cover glass 28 comprises an interposer region 29 in which an electrode 36, which is connected to the transmission line 25 formed on an upper surface of the dielectric submount 24, is formed to be drawn out. That is, through the electrode 36 formed in the interposer region 29, the transmission line 25 formed on the upper surface of the dielectric submount 24 of the bottom optical transmission unit 10 may be connected to an external circuit.

FIG. 3 is an interior cross-sectional view of a top optical transmission unit 20, which is a second part of the stacked-type optical transmission module according to the exemplary embodiment of the present disclosure.

The difference from the bottom optical transmission unit 10 of FIG. 1 is that the half-wave plate 18 (FIG. 1) capable of rotating the polarization of light is not included, and thus, a P-polarization light 17′ output from an LD 20′ is emitted as an output light 23 of the P-polarization light without performing polarization rotation. Other than that, the top optical transmission unit 20 is configured in the same manner as the bottom optical transmission unit 10.

As described above, the half-wave plate 18 (see FIG. 1) may be located only on one of the bottom optical transmission unit 10 or the top optical transmission unit 20, and in this case, only a direction of a polarized beam splitter (PBS) is changed in an optical multiplexer, which will be described in FIG. 4, according to the location of the half-wave plate 18 (FIG. 1).

FIG. 4 illustrates a stacked-type optical transmission module finally completed by stacking the bottom optical transmission unit 10 and the top optical transmission unit 20.

A support spacer 30, which is configured to space the bottom optical transmission unit 10 and the top optical transmission unit 20 from each other and support them, is interposed between the cover glasses 28 and 28′ respectively covered on the bottom optical transmission unit 10 and the top optical transmission unit 20.

An optical multiplexer 32, a lower interposer 34, and an upper interposer 34′ are installed in a space between the bottom optical transmission unit 10 and the top optical transmission unit 20 that are stacked with a gap due to the support spacer 30.

The lower interposer 34 is connected to the electrode 36, which is connected to the transmission line 25, through a via 33 formed in the interposer region 29 of the cover glass 28 for the bottom optical transmission unit 10 Similarly, the upper interposer 34′ is connected to an electrode 36′, which is connected to the transmission line 25, through a via 33′ formed in an interposer region 29′ of the cover glass 28′ for the top optical transmission unit 20. The lower interposer 34 and the upper interposer 34′ are bonded together by epoxy and exposed out of the package as a glass interposer terminal 38. Through the additional glass interposer terminal 38, signals to be transmitted are applied to the optical transmission module.

The optical multiplexer 32 includes a mirror 40, a PBS 42, a lens 44, and a fiber block 46 and multiplexes combined output light emitted from the bottom optical transmission unit 10 and the top optical transmission unit 20 and transmits the multiplexed output light through an optical fiber.

Referring to an enlarged view illustrated in a lower portion of FIG. 4, an operation of the optical multiplexer 32 may be seen. It can be seen that the P-polarization light 23 output from the top optical transmission unit 20 is incident on a P-polarization light-transmitting surface of the PBS 42 through the 45° mirror 40, and the S-polarization light 21 output from the bottom optical transmission unit 10 is changed in direction by 90° by the PBS 42 so that the light paths of the P-polarization light and the S-polarization light match each other. The P-polarization light and the S-polarization light multiplexed as described above are collected and transmitted to the fiber block 46 through the lens 44.

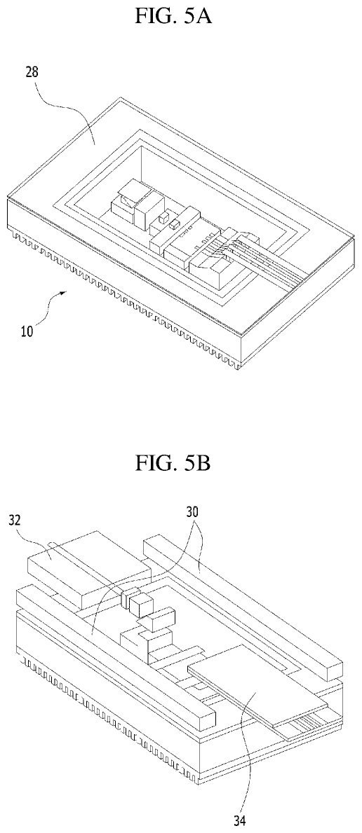

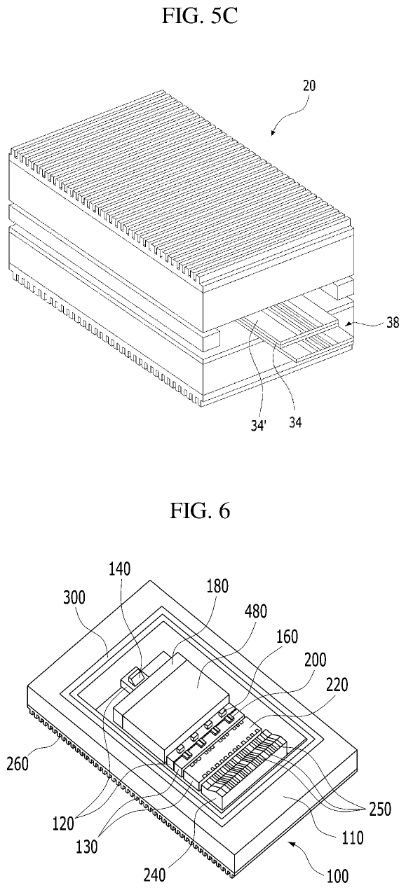

FIGS. 5A to 5C schematically illustrate a process sequence of manufacturing (packaging) a two-channel optical transmission module by stacking the one-channel bottom optical transmission unit 10 shown in FIG. 1 and the one-channel top optical transmission unit 20 shown in FIG. 3.

As a first packaging process, as shown in FIG. 5B, a fiber block 46 of an optical multiplexer 32 and optical components 40, 42, and 44 for multiplexing polarization light are optically aligned on a cover glass 28 of a bottom optical transmission unit 10, which is manufactured as shown in FIG. 5A, using light output from the bottom optical transmission unit 10 and then bonded with epoxy or the like, and then an interposer 34 is soldered. In addition, before stacking a top optical transmission unit 20, a support spacer 30 is bonded to the cover glass 28 of the bottom optical transmission unit 10.

Next, as a second packaging process (FIG. 5C), power is applied to the top optical transmission unit 20, which is manufactured by a process corresponding to that in FIG. 5B, to approximately position the top optical transmission unit 20 on the optical multiplexer 32, and then fine optical alignment is performed. Thereafter, the top optical transmission unit 20 is coupled to the bottom optical transmission unit 10 using epoxy and stacked thereon.

FIG. 6 illustrates an internal configuration of a four-channel bottom optical transmission unit 100 when the optical transmission module is extended to an eight-channel optical transmission module. The transmission line 250 and the LDD 220 are extended to four channels, and four light-output-channels having different wavelengths are multiplexed into one light path through a four-channel wavelength division multiplexer 480. In this case, the wavelength division multiplexer 480 may be in the form of an arrayed waveguide grating (AWG) planar lightwave circuit (PLC) and a ZigZag filter block. Depending on the form of the wavelength division multiplexer 480, a focusing lens or a collimating lens may be used for a lens 160. Further, a four-channel top optical transmission unit (not shown) has a structure in which a half-wave plate 180 is omitted and is similar to the bottom optical transmission unit 100, and the coupled bottom and top optical transmission units may be manufactured in the same optical multiplexer structure as the two-channel optical transmission module described above with reference to FIG. 4.

As described above, the eight-channel optical transmission module composed of four channels in a bottom side and four channels in a top side may be manufactured, and even in this case, heat emission may be effectively performed by separately arranging a heat sink 260 in each of the bottom optical transmission unit and the top optical transmission unit.

Conventionally, in the manufacturing of a four or more-channel optical transmission module utilizing a wavelength division multiplexer, packaging difficulty is rapidly increased according to the increase in channel, resulting in a drop in product completion yield. However, when the present disclosure is applied, in manufacturing an optical transmission module with an eight-channel light source, light may be multiplexed using polarization characteristics and a PBS so that four channels may be distributed to each of the bottom optical transmission unit and the top optical transmission unit, thereby reducing manufacturing difficulty.

Unlike a conventional multi-channel optical module, a multi-channel optical module of the present disclosure is manufactured by stacking a first optical transmission unit and a second optical transmission unit using a wafer-level packaging process, and thus has an advantage of being applicable to a mass production process. In addition, since a stacked structure of the first and second optical transmission units is a structure in which both light output is combined, effective heat dissipation performance can be obtained by improving from a conventional one side heat dissipation structure to a first/second both sides heat dissipation structure, and a mounting area per unit module can be minimized by reducing a mounting area per transmission channel by half.

Although the present disclosure has been described in detail above with reference to the exemplary embodiments, those of ordinary skill in the technical field to which the present disclosure pertains should be able to understand that various modifications and alterations can be made without departing from the technical spirit or essential features of the present disclosure. Therefore, it should be understood that the disclosed embodiments are not limiting but illustrative in all aspects. Further, the scope of the present disclosure is defined not by the above description but by the following claims, and it should be understood that all changes or modifications derived from the scope and equivalents of the claims fall within the scope of the present disclosure.

What is claimed is:

1. A stacked-type optical communication module comprising:
a first optical transmission unit manufactured using a wafer-level packaging process;
a first heat sink comprised in the first optical transmission unit and configured to emit heat generated by the first optical transmission unit;
a second optical transmission unit manufactured using the wafer-level packaging process and stacked on the first optical transmission unit; and
a second heat sink comprised in the second optical transmission unit and configured to emit heat generated by the second optical transmission unit.

2. The stacked-type optical communication module of claim 1, further comprising an optical multiplexer configured to multiplex light emitted from the first optical transmission unit and light emitted from the second optical transmission unit.

3. The stacked-type optical communication module of claim 2, wherein the optical multiplexer comprises a polarized beam splitter (PBS) configured to match a light path of the light emitted from the second optical transmission unit and a light path of the light emitted from the first optical transmission unit to each other.

4. The stacked-type optical communication module of claim 1, wherein
the first optical transmission unit comprises a first interposer connected to a signal transmission line, and
the second optical transmission unit comprises a second interposer connected to a signal transmission line.

5. The stacked-type optical communication module of claim 1, wherein the first optical transmission unit comprises at least one laser diode (LD), at least one lens, a half-wave plate, and a mirror that are formed on a substrate,
wherein a first polarization light emitted from the at least one LD is input to the half-wave plate through the at least one lens and converted into a second polarization light by the half-wave plate, and the converted second polarization light is changed in direction at the mirror and emitted to the outside.

6. The stacked-type optical communication module of claim 5, wherein the first optical transmission unit further comprises a cover glass configured to seal the at least one LD, the at least one lens, the half-wave plate, and the mirror that are formed on the substrate.

7. The stacked-type optical communication module of claim 5, further comprising a wavelength division multiplexer configured to multiplex N lights into one light when the first optical transmission unit comprises N LDs and N lenses (where N is an integer greater than or equal to two).

8. The stacked-type optical communication module of claim 1, wherein the second optical transmission unit comprises at least one laser diode (LD), at least one lens, and a mirror that are formed on a substrate,
wherein a first polarization light emitted from the at least one LD is input to the mirror through the at least one lens, changed in direction at the mirror, and emitted to the outside.

9. The stacked-type optical communication module of claim 8, wherein the second optical transmission unit further comprises a cover glass configured to seal the at least one LD, the at least one lens, and the mirror that are formed on the substrate.

10. The stacked-type optical communication module of claim 8, further comprising a wavelength division multiplexer configured to multiplex N lights into one light when the second optical transmission unit comprises N LDs and N lenses (where N is an integer greater than or equal to two).

11. A method of manufacturing a stacked-type optical transmission module, the method comprising:
manufacturing a first optical transmission unit using a wafer-level packaging process;
attaching a first heat sink, which is configured to emit heat, to the first optical transmission unit;
manufacturing a second optical transmission unit using the wafer-level packaging process;
attaching a second heat sink, which is configured to emit heat, to the second optical transmission unit; and
stacking the first optical transmission unit and the second optical transmission unit.

12. The method of claim 11, wherein the manufacturing the first optical transmission unit comprises forming at least one laser diode (LD), at least one lens, a half-wave plate, and a mirror on a substrate.

13. The method of claim 12, wherein the manufacturing the first optical transmission unit further comprises sealing the at least one LD, the at least one lens, the half-wave plate, and the mirror formed on the substrate with a cover glass.

14. The method of claim 12, wherein the manufacturing the first optical transmission unit comprises connecting a first interposer to a signal transmission line of the first optical transmission unit.

15. The method of claim 11, wherein the manufacturing the second optical transmission unit comprises forming at least one laser diode (LD), at least one lens, and a mirror on a substrate.

16. The method of claim 15, wherein the manufacturing the second optical transmission unit further comprises sealing the at least one LD, the at least one lens, and the mirror formed on the substrate with a cover glass.

17. The method of claim 11, wherein the manufacturing the second optical transmission unit comprises connecting a second interposer to a signal transmission line of the second optical transmission unit.

18. The method of claim 11, wherein the stacking the first optical transmission unit and the second optical transmission unit comprises additionally forming an optical multiplexer configured to multiplex light emitted from the first optical transmission unit and light emitted from the second optical transmission unit.
